(19) United States
(12) Patent Application Publication
(10) Pub. No.: US 2009/0056631 A1
(43) Pub. Date: Mar. 5, 2009

(54) APPARATUS FOR MANUFACTURING SEMICONDUCTOR LAYER

(75) Inventor: CHIH-MING LAI, Chu-Nan (TW)

Correspondence Address: PCE INDUSTRY, INC.;ATT. CHENG-JU CHIANG, 458 E. LAMBERT ROAD, FULLERTON, CA, 92835, US

(73) Assignee: FOXSEMICON INTEGRATED TECHNOLOGY, INC., Chu-Nan (TW)

(21) Appl. No.: 12/189,634

(22) Filed: Aug. 11, 2008

(30) Foreign Application Priority Data
Aug. 31, 2007 (CN) 200710201561.8

(51) Int. Cl. C23C 16/00

(52) U.S. Cl. 118/733; 118/715

(57) ABSTRACT

An apparatus for manufacturing a semiconductor layer on a substrate typically includes a reaction chamber, a first feed pipe, and a second feed pipe. The reaction chamber is configured for receiving the substrate therein. The first feed pipe and the second feed pipe communicate with the reaction chamber, providing a first raw material gas and a second raw material gas to the reaction chamber, respectively. The first feed pipe includes a first portion and a second portion. The first portion and the second portion are detachably connected to each other, allowing the second portion to be easily removed and replaced.

### BACKGROUND

1. Technical Field

The present invention relates to an apparatus for manufacturing a semiconductor layer on a substrate.

2. Discussion of Related Art

Nowadays, light emitting diodes (LEDs) are widely used in backlight modules because of their high brightness, low power consumption, and long lifespan. Generally, LEDs can be manufactured by the hydride vapour phase epitaxy (HVPE) method, the molecular beam epitaxy (MBE) method, or the metal-organic vapour phase epitaxy (MOVPE) method.

Referring to FIG. 8, an apparatus for manufacturing a gallium nitride (GaN) semiconductor layer by the HVPE method includes a reaction chamber 80, a first feed pipe 81, and a second feed pipe 82. The first feed pipe 81 and the second feed pipe 82 both communicate with the reaction chamber 80. A substrate 83 is positioned in the reaction chamber 80 for growing the GaN semiconductor layer.

The first feed pipe 81 is configured for feeding a first raw material gas (not labeled), usually a mixture of argon gas and hydrogen chloride gas, into the reaction chamber 80. The first feed pipe 81 includes an open-top container 85 containing molten gallium 84. When the mixture of argon gas and hydrogen chloride gas flows through the first feed pipe 81, the hydrogen chloride gas reacts with the molten gallium 84 to form gallium chloride and gallium trichloride according to the following chemical reactions: Ga+2HCl→GaCl+H₂, Ga+3HCl→GaCl₃+3H. The gallium chloride and gallium trichloride flow into the reaction chamber 80 through an opening 810 parallel to a top surface 830 of the substrate 83 and diffuse onto the top surface 830.

The second feed pipe 82 is configured for feeding a second raw material gas (not labeled) consisting mainly of ammonia gas into the reaction chamber 80. The ammonia gas also flows into the reaction chamber 80 parallel to the top surface 830 of the substrate 80, and reacts with the gallium chloride from the first raw material gas thereby forming a GaN epitaxial semiconductor layer 86 on the substrate 83 according to the following chemical reaction: 3GaCl+NH₃→GaN+3HCl.

However, an accumulation of GaN forms at the opening 810 of the first feed pipe 81. After many cycles, the accumulation will gradually jam the opening 810, thereby decreasing the mass flow rate of the first raw material gas and decreasing the growing rate of the GaN epitaxial semiconductor layer.

Referring to FIG. 9, another apparatus for manufacturing a gallium nitride (GaN) semiconductor layer by the HVPE method includes a reaction chamber 90, an outer pipe 92, a first feed pipe 91 invaginated in the outer pipe 92 and in communication with the reaction chamber 90, and a gas inlet 94. During fabrication, hydrogen chloride gas flows through the first feed pipe 91 and reacts with the molten gallium, forming a first raw material gas of gallium chloride and gallium trichloride. Thereafter, the first raw material gas flows into the reaction chamber 90 through an opening 910 and diffuses to a sloping top surface (not labeled) of a substrate (not labeled). Ammonia gas is introduced into the reaction chamber 90 through the gas inlet 94. Inert gas is introduced into the reaction chamber 90 by the outer pipe 92, to preventing the first raw material gas from reacting with the ammonia gas around the opening 910. However, even with this configuration, GaN will eventually accumulate and block the opening 910.

As a result, the first feed pipes 81, 91 in FIG. 8 and FIG. 9, respectively, must be replaced and the molten gallium transferred into the new first feed pipes 81, 91. During transfer, the molten gallium may become contaminated resulting in degradation in the quality of the GaN semiconductor.

Therefore, an improved apparatus for manufacturing a semiconductor layer structure with high efficiency and quality is desired to overcome the above-described deficiencies.

### SUMMARY

An apparatus for manufacturing a semiconductor layer, in accordance with a present embodiment, is provided. The apparatus includes a reaction chamber, a first feed pipe, and a second feed pipe. The reaction chamber is configured for receiving a substrate therein. The first feed pipe communicates with the reaction chamber, providing a first raw material gas to the reaction chamber. The second feed pipe communicates with the reaction chamber, providing a second raw material gas to the reaction chamber. The first feed pipe includes a first portion and a second portion that are detachably connected to each other such that the second portion can be replaced.

Other advantages and novel features of the present apparatus for manufacturing a semiconductor layer and the embodiments will become more apparent from the following detailed description and claims and the accompanying drawings.

### BRIEF DESCRIPTION OF THE DRAWINGS

Many aspects of the present apparatus for manufacturing a semiconductor layer can be better understood with reference to the following drawings. The components in the drawings are not necessarily drawn to scale, the emphasis instead being placed upon clearly illustrating the principles of the present apparatus for manufacturing a semiconductor layer. Moreover, in the drawings, like reference numerals designate corresponding parts throughout the several views.

FIG. 1 is a schematic view of a first embodiment of an apparatus for manufacturing a semiconductor layer of the present invention;

FIG. 2 is a schematic view of a second embodiment of an apparatus for manufacturing a semiconductor layer;

FIG. 3 is a side view of the interior structure of the apparatus for manufacturing a semiconductor layer of FIG. 2;

FIG. 4 is a plot of semiconductor material growing rate versus hydrogen chloride gas flowrate when semiconductor layer structure is produced respectively by general apparatus and apparatus of the second exemplary embodiment;

FIG. 5 is a schematic view of another embodiment of an apparatus for manufacturing a semiconductor layer, the apparatus including a second feed pipe having a plurality of gas outlets;

FIG. 6 is a schematic view of a further embodiment of an apparatus for manufacturing a semiconductor layer, the apparatus including a plurality of first feed pipes;

FIG. 7 is a schematic view of a still further embodiment of an apparatus for manufacturing a semiconductor layer, the apparatus including a first feed pipe that is quadrate;

FIG. 8 is a schematic view of a conventional apparatus for manufacturing semiconductor layer; and

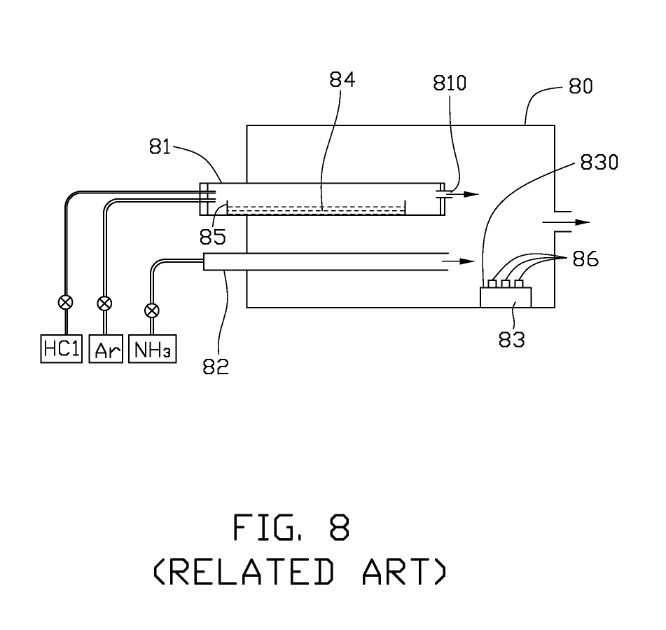

FIG. 9 is a schematic view of another conventional apparatus for manufacturing semiconductor layer.

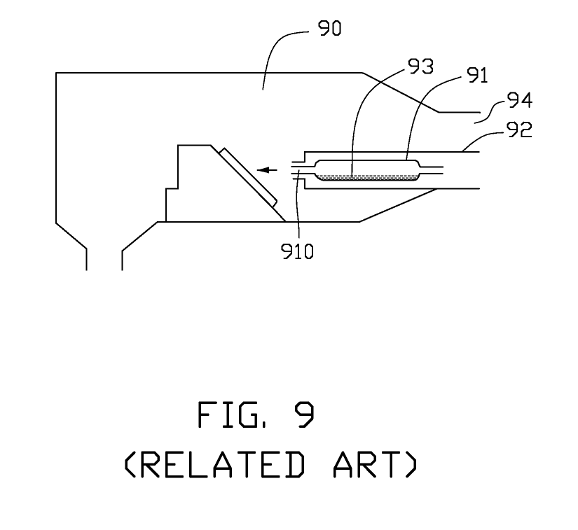

### DETAILED DESCRIPTION OF THE EMBODIMENTS

Reference will now be made to the drawings to describe embodiments of the present apparatus for manufacturing a semiconductor layer in detail.

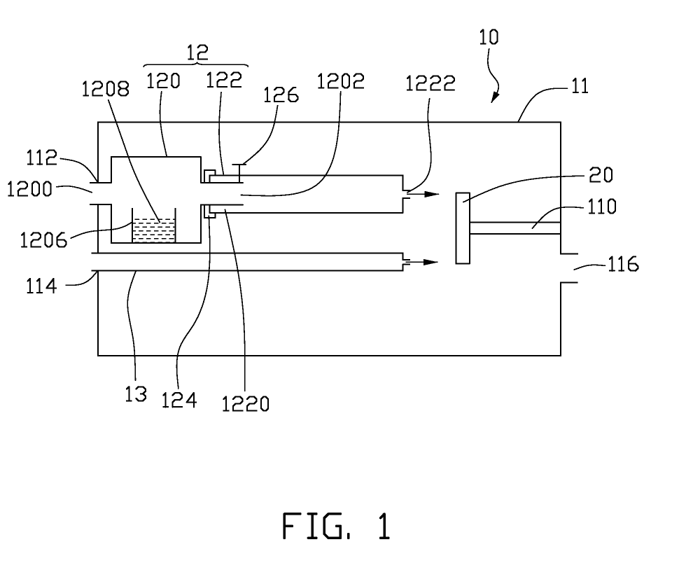

Referring to FIG. 1, an apparatus 10 for manufacturing a semiconductor layer according to a first embodiment is shown. The apparatus 10 includes a reaction chamber 11, a first feed pipe 12, and a second feed pipe 13. Typically, the apparatus 10 is capable of and used for manufacturing a plurality of semiconductor layer.

The reaction chamber 11 operates in a heating device (not shown), such as a blast furnace, to provide the proper thermal (e.g., 900-1200 degrees Celsius) and pressure (e.g., 0.5-1 atmosphere) environment suitable for growing epitaxial semiconductor layer. The reaction chamber 11 includes a first opening 112 in communication with the first feed pipe 12, a second opening 114 in communication with the second feed pipe 13, and a gas outlet 116 positioned in the side wall of the reaction chamber 11. A supporting member 110, configured for supporting a substrate 20, is positioned in the reaction chamber 11. The substrate 20 can be made of sapphire and is used for growing a semiconductor epitaxial layer thereon. The gas outlet 116 is configured for releasing waste gas.

The first feed pipe 12 is configured for feeding a first raw material gas (not shown) into the reaction chamber 11. In one embodiment, the first feed pipe 12 may be a ring-shaped pipe. The first feed pipe 12 comprises a first portion 120 and a second portion 122.

The first portion 120 includes a gas inlet 1200, a gas outlet 1202, and a raw material laying area 1206. The gas inlet 1200 and the gas outlet 1202 are located at each end of the raw material laying area 1206. The gas inlet 1200 communicates with an exterior gas source (not illustrated) outside of the reaction chamber 11. The gas outlet 1202 communicates with the second portion 122. The raw material laying area 1206 is configured for containing molten metal 1208. Typically, the molten metal 1208 is selected from group IIIA of the periodic table, such as gallium, aluminum, or indium. Halide gas from the exterior gas source flows through the raw material laying area 1206 via the gas inlet 1200, and reacts with the molten metal 1208 forming a metal halide that flows into the second portion 122 through the gas outlet 1202.

The second portion 122 includes a gas inlet 1220 on one end and a first outlet 1222 on the other end. The second portion 122 is detachably connected to the first portion 120. In the first embodiment, the gas inlet 1220 of the second portion 122 has a diameter slightly larger than that of the gas outlet 1202 of the first potion 120, so that the gas outlet 1202 extends into the gas inlet 1220 and the first portion 120 is partly invaginated in the second portion 122. The first raw material gas released from the gas outlet 1202 can flow into the second portion 122 through the gas inlet 1220 and flow into the reaction chamber 11 through the first outlet 1222 towards a top surface 200 of the substrate 20.

In another embodiment, a sealing member 124 (e.g., a sealing ring) is configured for sealing the junction of the gas outlet 1202 and the gas inlet 1220.

In another embodiment, the first feed pipe 12 further includes a fixing member 126. The fixing member 126 (e.g., screw or bolt) is positioned at the junction of the gas outlet 1202 and the gas inlet 1220 to fix the first portion 120 and the second portion 122 together.

However, the connecting relationship of the first portion 120 and the second portion 122 is not limited to the above-mentioned configurations. In another embodiment, the first portion 120 and the second portion 122 can connect to each other by an additional joining pipe (not shown). In yet another embodiment, the gas outlet 1202 of the first portion 120 can have a diameter slightly larger than the gas inlet 1220 of the second portion 122, allowing the gas inlet 1220 to extend into the gas outlet 1202 such that the second portion 122 is partly invaginated in the first portion 120.

Furthermore, the first feed pipe 12 can also be made of quartz, ceramic such as pyrolytic boron nitride (PBN) or boron nitride (BN), metal with high melting point such as tungsten or molybdenum, or aluminum oxide, to be more effective in avoiding accumulation of GaN.

The second feed pipe 13 is positioned in the reaction chamber 11 communicating with the second opening 114, and is configured for feeding a second raw material gas (not shown), such as ammonia gas, into the reaction chamber 11. The first and second raw material gases are mixed in the reaction chamber 11 and react with each other, thereby growing a GaN epitaxial layer on the substrate 20. The second feed pipe 13 can be a ring-shaped pipe or a square pipe. In the first embodiment, the second feed pipe 13 is a square pipe.

Due to the first and second portions 120, 122 being detachably connected to each other, when the first outlet 1222 of the second portion 122 is blocked by accumulation of GaN, the second portion 122 can be replaced without any need for replacing the first portion 120. As such, the molten metal disposed in the first portion 120 will not be contaminated.

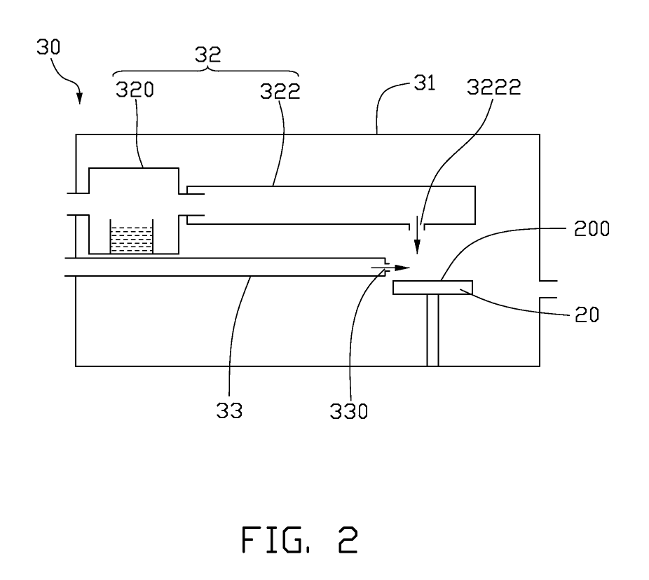

Referring to FIG. 2, an apparatus 30 for manufacturing semiconductor layers according to a second embodiment is shown. The apparatus 30 has a configuration similar to the apparatus 10 of the first embodiment in FIG. 1. The apparatus 30 includes a reaction chamber 31 configured for receiving the substrate 20, and a first feed pipe 32 and a second feed pipe 33 configured for feeding a first raw material gas (not shown) and a second raw material gas (not shown), respectively, into the reaction chamber 31.

The first feed pipe 32 includes a first portion 320 and a second portion 322, the second portion 322 includes a gas outlet 3222. The first feed pipe 32 is a columniform pipe. The second feed pipe 33 includes a second outlet 330. The opening direction of the gas outlet 3222 intersects the opening direction of the second outlet 330 in a way that allows the first raw material gas released from the gas outlet 3222 and the second raw material gas released from the second outlet 330 to mix adequately and increase the growth rate of semiconductor layers. In one embodiment, the gas flow of the gas outlet 3222 is perpendicular to the gas flow of the second outlet 330.

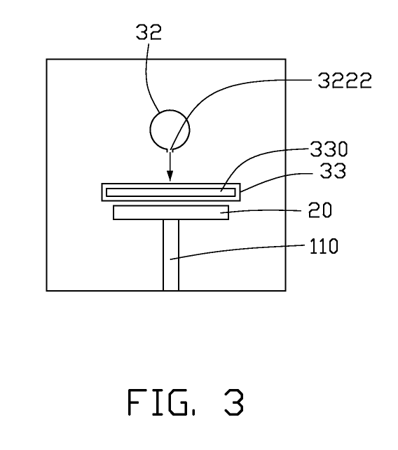

Referring also to FIG. 3, the opening direction of the second outlet 330 is perpendicular to the paper surface and the opening direction of the gas outlet 3222 is parallel to the paper surface, such that the first raw material gas released from the gas outlet 3222 and the second raw material gas released from the second outlet 330 respectively flow towards the top surface 200 of the substrate 20.

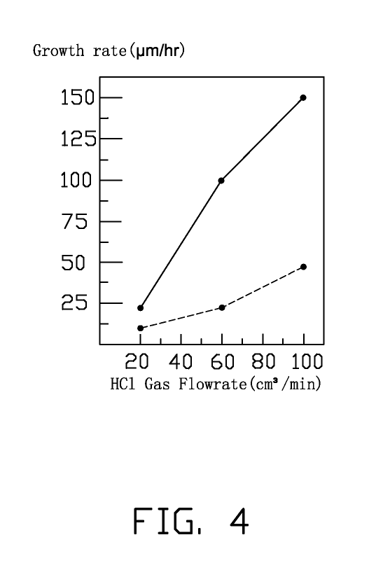

Referring to FIG. 4, this graph shows that a “perpendicular flow” type apparatus of the present embodiment, indicated by solid lines (not labeled), has a distinctly higher semiconductor layer growing rate than a conventional “parallel flow” type apparatus, indicated by dashed lines (not labeled).

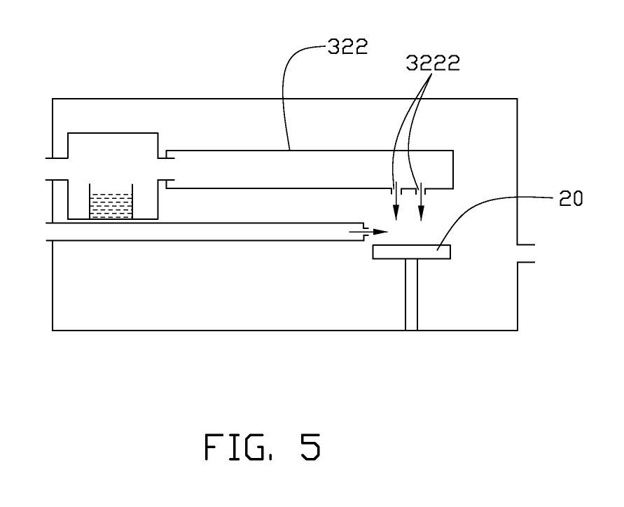

Referring also to FIG. 5, an apparatus 30 for manufacturing semiconductor layers according to a second embodiment is shown. It should be noted that the gas outlet 3222 of the second portion 322 shown in FIG. 3 is not limited to being a single gas outlet. As illustrated in FIG. 5, the second portion 322 can include two or more gas outlets 3222. Typically, each gas outlet 3222 has an opening direction parallel to the opening directions of the other gas outlets 3222.

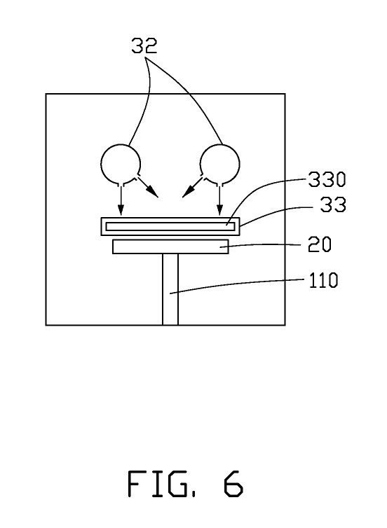

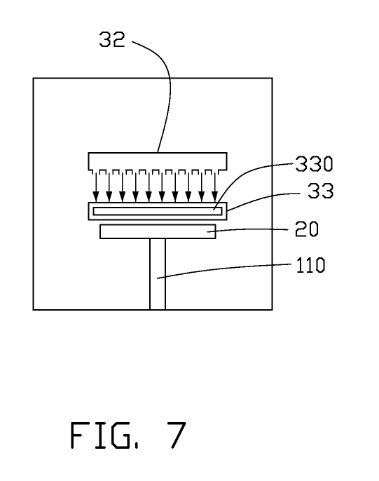

Referring also to FIG. 6, there can two or more first feed pipes 32. In the typical embodiment illustrated, each gas outlet 3222 of each first feed pipe 32 can have an opening direction parallel or perpendicular to the opening direction of the other gas outlet 3222 of the same first feed pipe 32. In addition, the gas outlets 3222 of one first feed pipe 32 can have opening directions parallel and/or perpendicular to the opening directions of the gas outlets 3222 of the other first feed pipe 32. The first feed pipe 32 is not limited to being a columniform pipe. For example, the first feed pipe 32 can instead be a square pipe (as shown in FIG. 7), or a pipe with another shape.

It is to be understood, however, that even though numerous characteristics and advantages of the present embodiments have been set forth in the foregoing description together with details of the structures and functions of the embodiments, the disclosure is illustrative only, and changes may be made in detail, especially in matters of shape, size, and arrangement of parts, within the principles of the invention to the full extent indicated by the broad general meaning of the terms in which the claims are expressed.

What is claimed is:

1. An apparatus for manufacturing a semiconductor layer, comprising:
a reaction chamber configured for receiving a substrate therein;
at least one first feed pipe in communication with the reaction chamber, and capable of providing a first raw material gas to the reaction chamber, wherein the at least one first feed pipe comprises a first portion and a second portion, and the first portion and the second portion are detachably connected to each other; and
a second feed pipe in communication with the reaction chamber, and capable of providing a second raw material gas to the reaction chamber.

2. The apparatus according to claim 1, wherein the first portion is partly invaginated in the second portion.

3. The apparatus according to claim 2, wherein the at least one first feed pipe further includes a sealing member configured for sealing the junction of the first portion and the second portion.

4. The apparatus according to claim 2, wherein the at least one first feed pipe further includes a fixing member configured for fixing the first portion and the second portion.

5. The apparatus according to claim 1, wherein the at least one first feed pipe further includes at least one first outlet capable of releasing the first raw material gas to the reaction chamber; the second feed pipe includes a second outlet capable of releasing the second raw material gas to the reaction chamber; and an opening direction of the at least one first outlet intersects that of the second outlet.

6. The apparatus according to claim 5, wherein the opening direction of the at least one first outlet is perpendicular to that of the second outlet.

7. The apparatus according to claim 5, wherein the at least one first outlet is a plurality of first outlets, and opening directions of the first outlets are parallel to each other.

8. The apparatus according to claim 5, wherein the at least one first outlet is a plurality of first outlets, and opening directions of at least two of the first outlets are different from each other.

9. The apparatus according to claim 5, wherein the at least one first outlet is a plurality of first outlets, and opening directions of the first outlets are parallel to each other.

10. The apparatus according to claim 1, wherein the at least one first feed pipe is made of a material selected from the group consisting of quartz, ceramic, tungsten, molybdenum, and aluminum oxides.

11. The apparatus according to claim 1, wherein the first feed pipe is a ring-shaped pipe, a squared pipe or a columniform pipe.

12. The apparatus according to claim 1, wherein the second feed pipe is a ring-shaped pipe or a squared pipe.

13. The apparatus according to claim 1, wherein the first portion includes a gas inlet, a raw material laying area, and a gas outlet; the gas inlet is in communication with an exterior of the reaction chamber and is capable of feeding halide gas; the raw material laying area is capable of receiving molten group IIIA metal such that the halide gas reacts with the molten group IIIA metal producing metal halide; and the gas outlet communicates with the second portion to allow the metal halide to flow from the gas outlet to the second portion.

14. An apparatus for manufacturing a semiconductor layer, comprising:
a reaction chamber configured for receiving a substrate therein;
at least one first feed conduit in communication with the reaction chamber, and capable of providing a first raw material gas to the reaction chamber, wherein the at least one first feed conduit comprises a first portion and a second portion, and the first portion and the second portion are detachably connected to each other; and
a second feed conduit in communication with the reaction chamber, and capable of providing a second raw material gas to the reaction chamber.
